(19) United States
(12) Patent Application Publication
(10) Pub. No.: US 2005/0269640 A1
(43) Pub. Date: Dec. 8, 2005

(54) Semiconductor device and manufacturing method thereof

(76) Inventors: Satoshi Shimamoto, Hitachinaka (JP); Katsuhiko Ichinose, Toride (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/143,716

(22) Filed: Jun. 3, 2005

(30) Foreign Application Priority Data
Jun. 4, 2004 (JP) 2004-166879

(51) Int. Cl. H01L 27/01

(52) U.S. Cl. 257/351

(57) ABSTRACT

A technique for forming a plurality of MISFETs having desired threshold voltages on a SOI substrate is provided. Each gate electrodes of pMIS and nMIS is made of a metal film having a work function approximate to that of a channel region of the pMIS, such as a molybdenum or ruthenium film, and a rise of the threshold voltage due to the metal film is reduced by inducing a positive fixed charge in a BOX layer. Thereby, the pMIS and nMIS having the desired threshold voltages can be formed on the SOI substrate.

### CROSS-REFERENCE TO RELATED APPLICATION

The present application claims priority from Japanese patent application No. JP 2004-166879 filed on Jun. 4, 2004, the content of which is hereby incorporated by reference into this application.

### BACKGROUND OF THE INVENTION

The present invention relates to a semiconductor device and a manufacturing method thereof and especially to a technique effectively applied to manufacture of a MISFET (Metal Insulator Semiconductor Field Effect Transistor) formed on a SOI (Silicon On Insulator) substrate.

When a CMOS (Complementary Metal Oxide Semiconductor) device with a gate length of 65 nm or less conforms to a conventional scaling law, device performance is difficult to improve and there arises a problem that the device performance is deteriorated to the contrary. In the CMOS device with a gate length of, for example, 40 nm, a halo region with a relatively high concentration is formed on each bottom of source and drain regions in order to reduce short channel effect. However, by forming the halo region, current drive capability is reduced due to an increase of impurity scattering in a channel region, or a failure etc. with respect to a high-speed operation occurs due to enlargement of a pn junction between the source and the substrate.

Therefore, it is rapidly required to develop a new shallow junction technique or change a process structure. A full-depletion type SOI device is proposed as one example of a change of the process structure (Patent Document 1: Japanese Patent Laid-open No. 2000-183355 and Patent Document 2: Japanese Patent Laid-open No. 2000-277737), for example. The full-depletion type SOI device is a SOI device in which the thickness of an SOI layer is set to 50 nm or less and the SOI layer is fully depleted.

### SUMMARY OF THE INVENTION

However, the full-depletion type SOI device has various technical problems as described below.

In the full-depletion type SOI device, since the SOI layer is depleted, an impurity concentration in the channel region cannot be relatively increased and a threshold voltage is determined based on the impurity concentration in the channel region formed in the SOI layer with a thickness of 50 nm or less. Therefore, only the MISFET having the threshold voltage on a significantly depletion side can be obtained. However, in consideration of reductions of a LSI (Large Scale Integration) circuit and standby power consumption, the MISFET having the threshold voltage on an enhancement side is absolutely needed. The MISFET having the threshold voltage on the enhancement side can be formed by introducing impurities into the channel region. However, the impurity concentration of the channel region cannot be relatively increased in order to keep the SOI layer in a full depletion state or to use a characteristic such as a small substrate effect constant.

When a metal material is used for the gate, the threshold voltage of the MISFET can be controlled by selecting the metal material because the threshold voltage of the MISFET depends on the metal material. However, in order to form a plurality of MISFETs with mutually different threshold voltages, it becomes necessary to selectively use the gate materials, so that selecting the gate materials becomes complicated. That is, it is difficult to optimize the threshold voltages of the plurality of MISFETs only by selecting the metal materials.

Meanwhile, in the case of a CMOS device in which a dual gate is adopted, a gate whose conductivity type is “P” is used for a p channel type MISFET and a gate whose conductivity type is “n” is used for an n channel type MISFET, so that the threshold voltages of the p channel type MISFET and the n channel type MISFET can be controlled, respectively. However, even if the CMOS device adopting the dual gate is formed on the SOI substrate, the impurity concentration of the channel region cannot be relatively increased. Accordingly, the threshold voltages of the p channel type MISFET and the n channel type MISFET are not on the enhancement side but on the depletion side.

An object of the present invention is to provide a technique for forming a plurality of MISFETs having the desired threshold voltages on a SOI substrate.

The above and other objects and novel features of the present invention will be apparent from the description of this specification and the accompanying drawings.

Outlines of representative ones of inventions disclosed in the present application will be briefly described as follows.

A semiconductor device according to the present invention comprises: a SOI substrate in which a SOI layer is formed on a supporting substrate through a BOX layer; an n-type well formed in the SOI layer; a p-type well formed in the SOI layer; a p channel type MISFET formed in the n-type well; an n channel type MISFET formed in the p-type well; and fixed charges induced in the BOX layer under the p-type well.

A manufacturing method for a semiconductor device according to the present invention, in which p and n channel type MISFETs are formed on a SOI substrate in which a SOI layer is formed on a supporting substrate through a BOX layer, comprises the steps of: forming n-type and p-type wells surrounded by a device isolation on the SOI layer; ion-implanting an impurity into the BOX layer under the p-type well to induce fixed charges in the BOX layer; forming gate insulators of the p and n channel type MISFETs on a surface of the SOI layer; forming gate electrodes of the p and n channel type MISFETs on the gate insulators by using the same material; ion-implanting a p-type impurity into the n-type well to form source and drain of the p channel type MISFET; and ion-implanting n-type impurity into the p-type well to form source and drain of the n channel type MISFET.

Effects obtained by representative ones of inventions disclosed in the present application will be briefly described as follows.

The plurality of MISFETs having the desired threshold voltages can be formed on the SOI substrate.

### BRIEF DESCRIPTION OF THE DRAWINGS

FIG. 1 is a sectional view of a principal portion of a SOI substrate showing a full-depletion type SOI device according to a first embodiment of the present invention.

FIG. 2 is a sectional view of a principal portion of a SOI substrate showing a manufacturing process for the full-depletion type SOI device in order of process according to a first embodiment of the present invention.

FIG. 3 is a sectional view of a principal portion of the SOI substrate showing the manufacturing process for the full-depletion type SOI device in order of process according to the first embodiment of the present invention.

FIG. 4 is a sectional view of a principal portion of the SOI substrate showing the manufacturing process for the full-depletion type SOI device in order of process according to the first embodiment of the present invention.

FIG. 5 is a sectional view of a principal portion of the SOI substrate showing the manufacturing process for the full-depletion type SOI device in order of process according to the first embodiment of the present invention.

FIG. 6 is a sectional view of a principal portion of the SOI substrate showing the manufacturing process for the full-depletion type SOI device in order of process according to the first embodiment of the present invention.

FIG. 7 is a sectional view of a principal portion of the SOI substrate showing the manufacturing process for the full-depletion type SOI device in order of process according to the first embodiment of the present invention.

FIG. 8 is a sectional view of a principal portion of the SOI substrate showing the manufacturing process for the full-depletion type SOI device in order of process according to the first embodiment of the present invention.

FIG. 9 is a sectional view of a principal portion of the SOI substrate showing the manufacturing process for the full-depletion type SOI device in order of process according to the first embodiment of the present invention.

FIG. 10 is a sectional view of a principal portion of the SOI substrate showing the manufacturing process for the full-depletion type SOI device in order of process according to the first embodiment of the present invention.

FIG. 11 is a sectional view of a principal portion of the SOI substrate showing the manufacturing process for the full-depletion type SOI device in order of process according to the first embodiment of the present invention.

FIG. 12 is a sectional view of a principal portion of the SOI substrate showing the manufacturing process for the full-depletion type SOI device in order of process according to the first embodiment of the present invention.

FIG. 13 is a sectional view of a principal portion of the SOI substrate showing the manufacturing process for the full-depletion type SOI device in order of process according to the first embodiment of the present invention.

FIG. 14 is a sectional view of a principal portion of the SOI substrate showing the manufacturing process for the full-depletion type SOI device in order of process according to the first embodiment of the present invention.

FIG. 15 is a sectional view of a principal portion of a SOI substrate showing a modified example of the full-depletion type SOI device according to a first embodiment of the present invention.

FIG. 16 is a sectional view of a principal portion of a SOI substrate showing a full-depletion type SOI device according to a second embodiment of the present invention.

FIG. 17 is a sectional view of a principal portion of a SOI substrate showing a modified example of the full-depletion type SOI device according to the second embodiment of the present invention.

FIG. 18 is a sectional view of a principal portion of a SOI substrate showing a full-depletion type SOI device according to a third embodiment of the present invention.

FIG. 19 is a sectional view of a principal portion of a SOI substrate showing a manufacturing process for the full-depletion type SOI device in order of process according to the third embodiment of the present invention.

FIG. 20 is a sectional view of a principal portion of the SOI substrate showing the manufacturing process for the full-depletion type SOI device in order of process according to the third embodiment of the present invention.

FIG. 21 is a sectional view of a principal portion of the SOI substrate showing the manufacturing process for the full-depletion type SOI device in order of process according to the third embodiment of the present invention.

FIG. 22 is a sectional view of a principal portion of the SOI substrate showing the manufacturing process for the full-depletion type SOI device in order of process according to the third embodiment of the present invention.

FIG. 23 is a sectional view of a principal portion of the SOI substrate showing the manufacturing process for the full-depletion type SOI device in order of process according to the third embodiment of the present invention.

FIG. 24 is a sectional view of a principal portion of the SOI substrate showing the manufacturing process for the full-depletion type SOI device in order of process according to the third embodiment of the present invention.

FIG. 25 is a sectional view of a principal portion of the SOI substrate showing the manufacturing process for the full-depletion type SOI device in order of process according to the third embodiment of the present invention.

FIG. 26 is a sectional view of a principal portion of the SOI substrate showing the manufacturing process for the full-depletion type SOI device in order of process according to the third embodiment of the present invention.

FIG. 27 is a sectional view of a principal portion of the SOI substrate showing the manufacturing process for the full-depletion type SOI device in order of process according to the third embodiment of the present invention.

FIG. 28 is a sectional view of a principal portion of the SOI substrate showing the manufacturing process for the full-depletion type SOI device in order of process according to the third embodiment of the present invention.

FIG. 29 is a sectional view of a principal portion of the SOI substrate showing the manufacturing process for the full-depletion type SOI device in order of process according to the third embodiment of the present invention.

FIG. 30 is a sectional view of a principal portion of the SOI substrate showing the manufacturing process for the full-depletion type SOI device in order of process according to the third embodiment of the present invention.

FIG. 31 is a sectional view of a principal portion of the SOI substrate showing the manufacturing process for the full-depletion type SOI device in order of process according to the third embodiment of the present invention.

FIG. 32 is a sectional view of a principal portion of the SOI substrate showing the manufacturing process for the full-depletion type SOI device in order of process according to the third embodiment of the present invention.

FIG. 33 is a sectional view of a principal portion of a SOI substrate showing a modified example of the full-depletion type SOI device according to the third embodiment of the present invention.

FIG. 34 is a sectional view of a principal portion of a SOI substrate showing a modified example of the full-depletion type SOI device according to the third embodiment of the present invention.

FIG. 35 is a sectional view of a principal portion of a SOI substrate showing a full-depletion type SOI device according to a fourth embodiment of the present invention.

FIG. 36 is a sectional view of a principal portion of a SOI substrate showing a modified example of the full-depletion type SOI device according to the fourth embodiment of the present invention.

FIG. 37 is a sectional view of a principal portion of a SOI substrate showing a full-depletion type SOI device according to a fifth embodiment of the present invention.

FIG. 38 is a sectional view of a principal portion of a SOI substrate showing a modified example of the full-depletion type SOI device according to the fifth embodiment of the present invention.

FIG. 39 is a sectional view of a principal portion of a SOI substrate showing a full-depletion type SOI device according to a sixth embodiment of the present invention.

FIG. 40 is a sectional view of a principal portion of a SOI substrate showing a manufacturing process for the full-depletion type SOI device in order of process according to the sixth embodiment of the present invention.

FIG. 41 is a sectional view of a principal portion of a SOI substrate showing the manufacturing process for the full-depletion type SOI device in order of process according to the sixth embodiment of the present invention.

FIG. 42 is a sectional view of a principal portion of a SOI substrate showing the manufacturing process for the full-depletion type SOI device in order of process according to the sixth embodiment of the present invention.

FIG. 43 is a sectional view of a principal portion of a SOI substrate showing a modified example of the full-depletion type SOI device according to the sixth embodiment of the present invention.

### DESCRIPTION OF THE PREFERRED EMBODIMENTS

In embodiments described below, when referring to the number of elements (including number of pieces, values, amounts, ranges, or the like), the number of elements is not limited to a specific number unless otherwise stated, or except the case where the number is apparently limited to a specific number in principle, or the like. The number larger or smaller than the specified number is also applicable. Further, in the embodiments described below, it goes without saying that the components (including element steps or the like) are not always essential unless otherwise stated, or except the case where the components are apparently essential in principle, or the like. Similarly, in the embodiments described below, when the shape of the components and the like, or the positional relation and the like thereof, or the like are mentioned, the substantially approximate and similar shapes and the like are included therein unless otherwise stated, or except the case where it can be conceived that they are apparently excluded in principle, or the like. This condition is also applicable to the numerical value and the range described above.

In addition, in the embodiments described below, a MISFET representative of a field effect transistor is abbreviated as “MIS”, an n channel type MISFET is abbreviated as “nMIS”, and a p channel type MISFET is abbreviated as “pMIS”. Further, even if the drawings used in the embodiments are plain views, semiconductor layers will be hatched in some cases in order to understand better the drawings.

Also, throughout all the drawings for explaining the embodiments, members with the same function are denoted by the same reference numeral and repetitive explanation thereof will be omitted. Hereinafter, the embodiments of the present invention will be detailed based on the drawings.

### First Embodiment

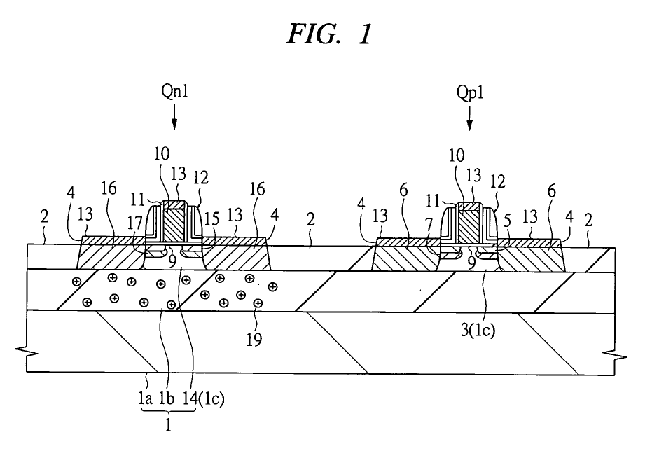

FIG. 1 is a sectional view of a principal portion of a SOI substrate showing a full-depletion type SOI device according to a first embodiment. A CMOS device is illustrated as the full-depletion type SOI device and the reference symbol “Qp1” is a pMIS and “Qn1” is an nMIS in FIG. 1.

The pMIS Qp1 and nMIS Qn1 are formed on a SOI substrate 1 manufactured by, for example, a SIMOX (Separation by Implanted Oxygen) method. The SOI substrate 1 is constituted so that a SOI layer (or body layer) 1c is formed on a supporting substrate la through a BOX (Buried Oxide) layer 1b. The BOX layer 1b is made of an insulating material having a thickness of, for example, approximately 100 nm and the SOI layer 1c is made of single crystal silicon having a thickness of, for example, 50 nm or less.

The pMIS Qp1 is formed on the SOI layer 1c and is formed in an n-type well 3 surrounded by device isolation 2. A silicon layer 4 is stacked on the n-type well 3 by a selective epitaxial growth method. The thickness of the silicon layer 4 is approximately 30 nm, for example. A pair of extension layers 5 is formed in the n-type well 3. A pair of diffusion layers 6 is formed in the n-type well 3 and the silicon layer 4. A pair of halo layers 7 is formed under the extension layer 5. The extension layer 5 is a semiconductor region which has a relatively low concentration and whose conductivity type is “p”. The diffusion layer 6 is semiconductor region which has a relatively high concentration and whose conductivity type is “p”. Source and drain is constructed by the pair of extension layers 5 and the pair of diffusion layers 6. The halo layer 7 is a semiconductor region, whose conductivity type is “n”, and serves as a punch-through stopper.

In order to suppress an increase of parasitic capacitance, the thickness of the SOI layer 1c and each depth of the pair of diffusion layers 6 are set so that the depletion layers of the source and drain at zero bias constantly contact with the BOX layer 1b.

A threshold voltage control layer is formed in the n-type well 3 between the pair of the extension layer 5. A gate insulator 9 is formed on the threshold voltage control layer. A gate electrode 10 made of a metal material is formed on the gate insulator 9. A silicon oxide film, an oxynitride film, or a high dielectric constant film is used as the gate insulator 9. A material being capable of setting the optimum threshold voltage for the pMIS Qp1, such as molybdenum (Mo) or ruthenium (Ru), is used as the metal material of the gate electrode 10.

A sidewall spacer 12, having a triple structure of an offset spacer 11 made of a silicon oxide film, a silicon nitride film, and a silicon oxide film, is formed on a side wall of the gate electrode 10. A silicide film 13 is formed on surfaces of the pair of diffusion layers 6 and a surface of the gate electrode 10 by a self-alignment silicide method. A cobalt silicide (CoSi₂) film or nickel silicide (NiSi) film is used as the silicide film 13, for example.

The nMIS Qn1 is formed on the SOI layer 1c and in a p-type well 14 surrounded by the device isolation 2. The silicon layer 4 is stacked on the p-type well 14 by a selective epitaxial growth method. The thickness of the silicon layer 4 is approximately 30 nm, for example. A pair of extension layers 15 is formed in the p-type well 14. A pair of diffusion layers 16 is formed in the p-type well 14 and the silicon layer 4. A pair of halo layers 17 is formed under the extension layer 15. The extension layer 15 is a semiconductor region which has a relatively low concentration and whose conductivity type is “n”. The diffusion layer 16 is a semiconductor region which has a relatively high concentration and whose conductivity type is “n”. Source and drain are constructed by the pair of extension layers 15 and the pair of diffusion layers 16, respectively. The halo layer 17 is a semiconductor region, whose conductivity type is “p”, and serves as a punch-through stopper.

In order to suppress an increase of the parasitic capacitance, the thickness of the SOI layer 1c and each depth of the pair of diffusion layers 16 are set so that the depletion layers of the source and drain at zero bias constantly contact with the BOX layer 1b.

A threshold voltage control layer is formed in the p-type well 14 between the pair of extension layers 15. The gate insulator 9 is formed on the threshold voltage control layer similarly to the pMIS Qp1. A gate electrode 10 is formed on the gate insulator 9. A material of the gate electrode 10 of the nMIS Qn1 is the same as that of the gate electrode 10 of the pMIS Qp1. Further, an offset spacer 11 and a sidewall spacer 12 are formed on a side wall of the gate electrode 10 similarly to the PMIS Qp1. A siliside film 13 is formed on the surfaces of the pair of the diffusion layers 16 and the surface of the gate electrode 10.

Positive fixed charges 19 are induced (formed) in the BOX layer 1b under the p-type well 14 in which the nMIS Qn1 is formed. Since the material of the gate electrode 10 of the nMIS Qn1 is the same as the material of the gate electrode 10 of the pMIS Qp1, the nMIS Qn1 normally has the threshold voltage on the enhancement side. However, the positive fixed charges 19 are induced in the BOX layer 1b, so that the nMIS Qn1 becomes in the same state as a state where the substrate bias is applied thereto. Therefore, the threshold voltage of the nMIS Qn1 is shifted to the depletion side. The positive fixed charges 19 can be induced by ion-implanting nitrogen and, for example, an amount of nitrogen introduced is 10¹⁷ cm⁻³ or more. Additionally, silicon oxynitride is formed in a portion of the BOX layer 1b by introducing nitrogen.

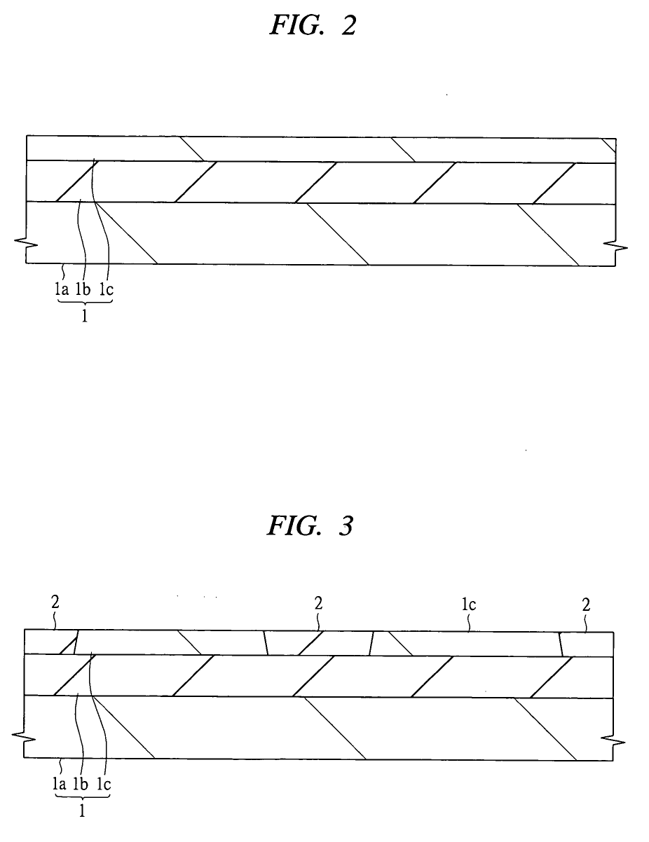

Next, a manufacturing method for the CMOS device according to the first embodiment shown in FIG. 1 will be described in order of process with reference to FIGS. 2 to 14.

Firstly, the SOI substrate 1 manufactured by the SIMOX method is prepared as shown in FIG. 2. The SOI substrate 1 comprises: the supporting substrate 1a made of p-type single crystal silicon with a specific resistance of approximately 1 to 10 Ωcm; the SOI layer 1c made of single crystal silicon; and the BOX layer 1b provided between the supporting substrate 1a and the SOI layer 1c. The thickness of the SOI layer 1c is, for example, approximately 50 nm or less and the thickness of the BOX layer 1b is, for example, approximately 100 nm.

Next, the device isolation 2 is formed in the SOI substrate 1 as shown in FIG. 3. The device isolation 2 is formed as follows. Since the SOI layer 1c is etched by using a photoresist film as a mask, a device isolation trench extending to the BOX layer 1b is formed and thereafter the SOI substrate 1 is thermal-oxidized at approximately 1000° C. to form, on an inner wall of the trench, a thin silicon oxide film with a thickness of approximately 10 nm. Such a thin silicon oxide film is formed in order to recover damage occurring on the inner wall of the trench due to dry etching and to reduce a stress occurring on an interface between an insulating film to be embedded into the trench in the next step and the supporting substrate 1a.

Next, an insulating film with a thickness of approximately 0.45 to 0.5 μm on the SOI layer 1c including the inside of the trench is deposited by a CVD (Chemical Vapor Deposition) method, and the insulating film on a top of the trench is polished by the CMP (Chemical Mechanical Polishing) method to planarize the surface thereof.

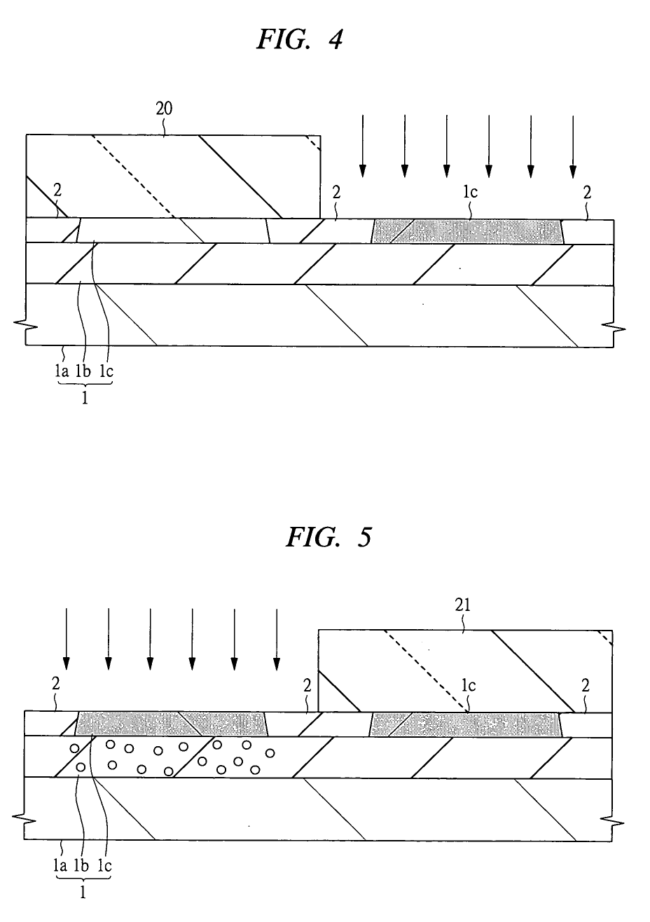

Next, as shown in FIG. 4, a forming region for nMIS Qn1 is covered with a photoresist film 20. An n-type impurity (e.g., phosphorus (P)) is ion-implanted into the SOI layer 1c of a forming region for pMIS Qp1. Further, a p-type impurity is ion-implanted into a channel region of the pMIS Qp1.

Next, as shown in FIG. 5, after the photoresist film 20 is removed, the forming region for pMIS Qp1 is formed is covered with the photoresist film 21. A p-type impurity (e.g., boron (B)) is ion-implanted into the SOI layer 1c of the forming region for nMIS Qn1. Further, an n-type impurity is ion-implanted into a channel region of the nMIS Qn1. Subsequently, nitrogen is ion-implanted into the BOX layer 1b. The above nitrogen is ion-implanted so that it has the maximum nitrogen concentration in the BOX layer 1b. It is ion-implanted with, for example, an injection energy of 40 keV and a dose amount of 5×10¹² cm⁻².

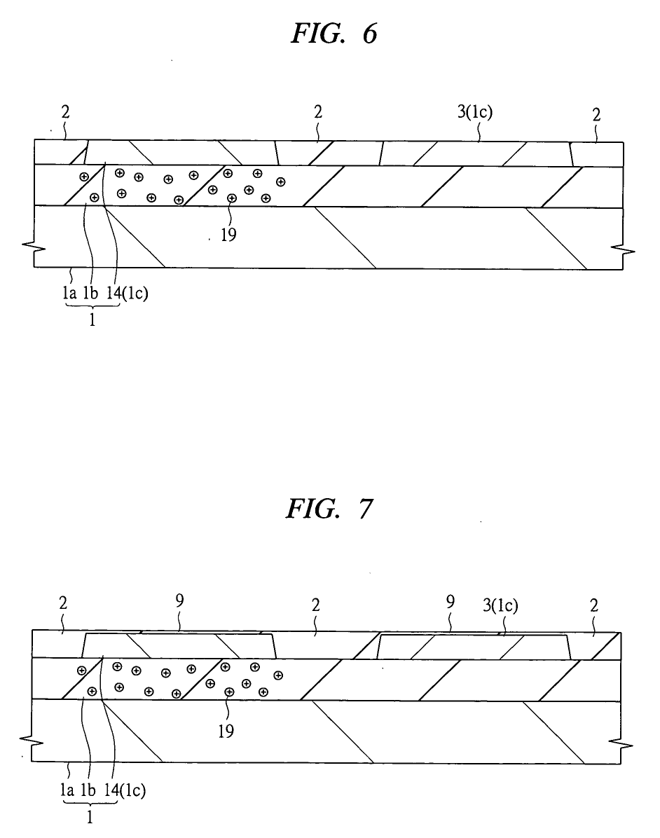

Next, as shown in FIG. 6, after the photoresist film 21 is removed, the above impurities are diffused by a heat treatment of approximately 1000° C., so that the n-type well 3, the p-type well 14, and the threshold voltage control layer are formed in the SOI layer 1c. Further, the positive fixed charges 19 are induced in the BOX layer 1b.

Next, as shown in FIG. 7, after the surface of the SOI layer 1c (n-type well 3 and p-type well 14) is wet-cleaned by using a fluorinated acid base cleaning liquid, the gate insulator 9 is formed on each surface of the n-type well 3 and the p-type well 14. A silicon oxide film, an oxynitride film, or a high dielectric constant film is used as the gate insulator 9. A ruthenium oxide (RuOₓ) film, a tantalum oxide (TaOₓ) film, a zirconium oxide (ZrOₓ) film, or a titanium oxide (TiOₓ) film can be used as the high dielectric constant film, for example.

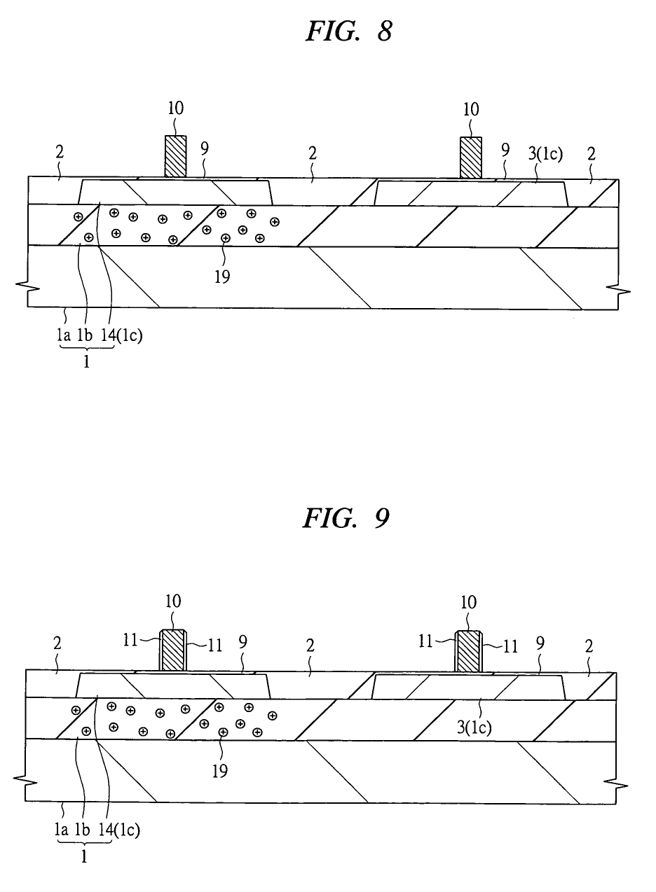

Next, as shown in FIG. 8, a metal film with a thickness of approximately 200 nm is deposited on the gate insulator 9 by the sputtering method. A material having a work function approximate to that of the channel region of the pMIS Qp1, for example, molybdenum or ruthenium, is used for the metal film. Subsequently, the metal film is dry-etched by using a photoresist film as a mask to form gate electrodes 10 made of metal films. If the material having the work function approximate to that of the channel region of the pMIS Qp1 is used for the gate electrode 10 of the nMIS Qn1, the threshold voltage of the nMIS Qn1 is increased on the enhancement side. However, the positive fixed charges 19 induced in the BOX layer 1b has the same function as that of the substrate bias, so that the threshold voltage of the nMIS Qn1 can be reduced to a predetermined value.

Next, as shown in FIG. 9, after an insulating film with a thickness of, for example, approximately 10 nm is deposited on the gate electrode 10 by the CVD method, the insulating film is anisotropic-etched to form the offset spacer 11 on each side wall of the gate electrodes 10.

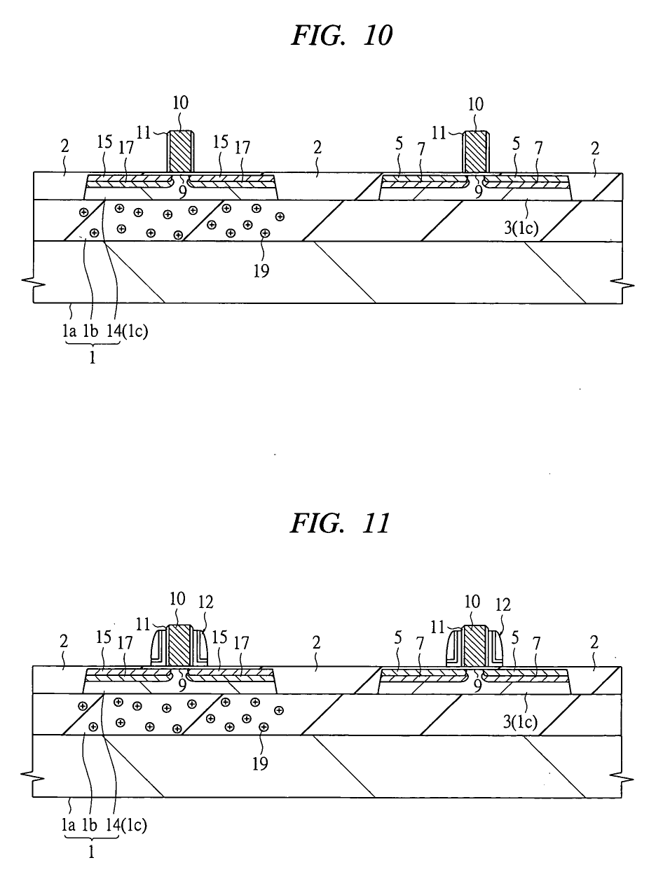

Next, as shown in FIG. 10, the forming region for nMIS Qn1 is covered with a photoresist film. The p-type impurities (e.g., boron) are ion-implanted into the n-type wells 3 on both sides of the gate electrode 10. The n-type impurity (e.g., arsenic (As)) is ion-implanted into a region deeper than the region into which the p-type impurity is ion-implanted. In the same way, the forming region for pMIS Qp1 is covered with the photoresist film. The n-type impurities (e.g., arsenic (As)) are ion-implanted into the P-type wells 14 on both sides of the gate electrode 10. The p-type impurity (e.g., boron) is ion-implanted into a region deeper than the region into which the n-type impurity is ion-implanted. Then, the impurities are diffused by a heat treatment to form the extension layer 5 and the halo layer 7 in the n-type well 3 and to form the extension layer 15 and the halo layer 17 in the p-type well 14.

Next, as shown in FIG. 11, an insulating film having a three-layer structure, in which a silicon oxide film, a silicon nitride film, and a silicon oxide film are sequentially deposited on the gate electrodes 10, is formed. Then, the insulating film is anisotropic-etched to form the sidewall spacer 12 on each side wall of the gate electrodes 10.

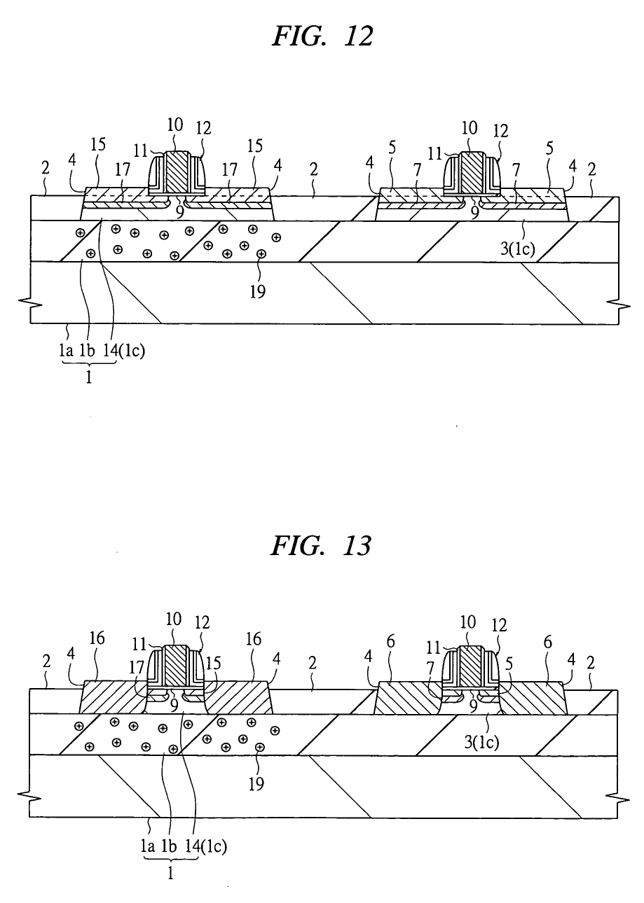

Next, as shown in FIG. 12, after the surface of the SOI layer (extension layers 5 and 15) 1c is wet-cleaned by using the fluorinated acid base cleaning liquid, the silicon film 4 is formed on the exposed surfaces of the SOI layer 1c by the selective epitaxial growth method. The thickness of the silicon film 4 is, for example, approximately 30 nm.

Next, as shown in FIG. 13, the forming region for nMIS Qn1 is covered with the photoresist film. The p-type impurities (e.g., boron) are ion-implanted into the n-type wells 3 on both sides of the sidewall spacer 12. In the same way, the forming region for pMIS Qp1 is covered with the photoresist film. The n-type impurities (e.g., arsenic) are ion-implanted into the p-type wells 14 on both sides of the sidewall spacer 12. Then, the impurities are diffused by the heat treatment to form the diffusion layers 6 in the n-type well 3 and the silicon layer 4 and to form the diffusion layers 16 in the p-type well 14 and the silicon layer 4. The extension layer 5 formed in the n-type well 3 and the diffusion layer 6 formed in the n-type well 3 and the silicon layer 4 serve as source and drain for the pMIS Qp1, respectively. The extension layer 15 formed in the p-type well 14 and the diffusion layer 16 formed in the p-type well 14 and the silicon layer 4 serve as source and drain for the nMIS Qn1.

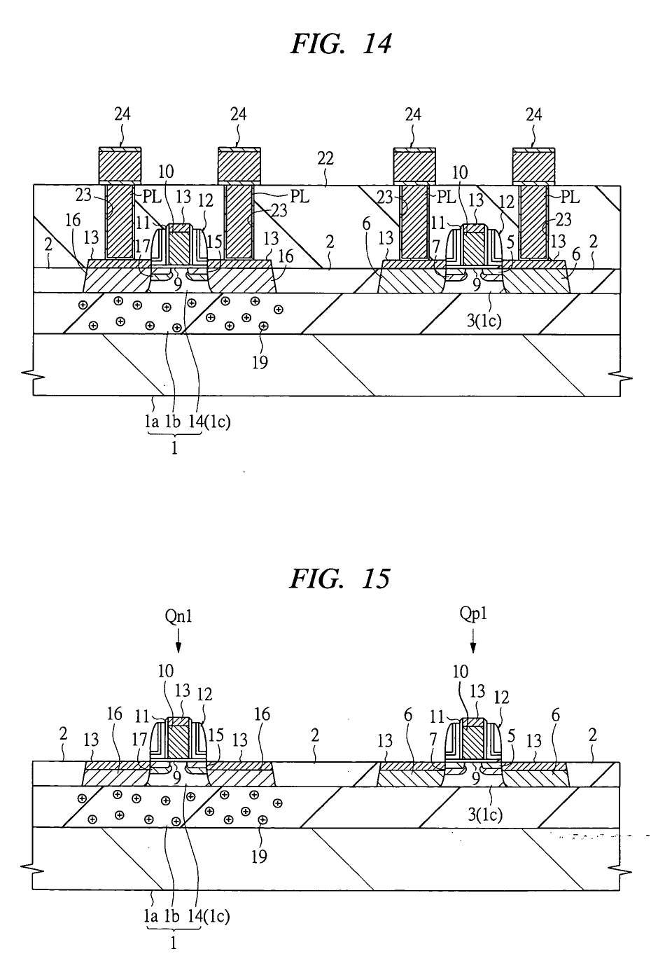

Next, as shown in FIG. 14, after each surface of the silicon layers 4 and the gate electrodes 10 is cleaned, a cobalt (Co) or nickel (Ni) film is deposited on each of the silicon layer 4 and the gate electrode 10 by the sputtering method. Subsequently, by performing the heat treatment, for example, at 600° C. for approximately one minute, the silicide films 13 are formed on exposed portions (diffusion layers 6 and 16) of the silicon layers 4 and the gate electrodes 10. Further, after the unreacted cobalt or nickel film is removed by etching, the resistance of the silicide films 13 is made lower by performing the heat treatment at 700 to 800° C. for approximately one minute.

Next, after an interlayer insulating film 22 is deposited on the silicide films 13, the interlayer insulating film 22 is etched by using a photoresist film as a mask to form connection holes 23. Then, after a metal film such as a tungsten film is deposited on the interlayer insulating film 22 including an interior of each connection hole 23, the metal film except for the connection holes 23 is removed by the CMP method to form plugs PL into the connection holes 23. Then, after a metal film, e.g., a laminated film made of a titanium nitride (TiN) film, an aluminium (Al) alloy film, and a titanium nitride film is deposited on the interlayer insulating film 22, the metal film is etched by using a photoresist film as a mask to form wirings 24. Thereby, the CMOS device according to the first embodiment is almost completed.

Note that, in the first embodiment, the diffusion layer 6 of the pMIS Qp1 and the diffusion layer 16 of the nMIS Qn1 have been formed in the silicon layers 4 laminated on the SOI layer 1c and in the SOI layer 1c . However, as shown in FIG. 15, the diffusion layer 6 of the pMIS Qp1 and the diffusion layer 16 of the nMIS Qn1 may be formed only in the SOI layer 1c without forming the silicon layer 4.

Thus, according to the first embodiment, the gate electrodes 10 of the pMIS Qp1 and nMIS Qn1 are made of a metal film having a work function approximate to that of the channel region of the pMIS Qp1, and a rise in the threshold voltage of the nMIS Qn1 due to use of the metal film is reduced by the positive fixed charges 19 induced in the BOX layer 1b. Therefore, the pMIS Qp1 and the nMIS Qn1 having the desired threshold voltages can be formed on the SOI substrate 1.

### Second Embodiment

In the above-described first embodiment, the material having a work function approximate to that of the channel region of the pMIS Qp1, such as molybdenum or ruthenium, is used as a gate material of each gate electrode 10 of the pMIS Qp1 and nMIS Qn1 to control the threshold voltage of the pMIS Qp1, and the threshold voltage of the nMIS Qn1 is controlled by the positive fixed charges 19 induced in the BOX layer 1b under the p-type well 14. However, in this second embodiment, a material having a work function approximate to that of the channel region of the nMIS, such as platinum (Pt) or lead (Pb), is used as a gate material of each of the PMIS and nMIS to control the threshold voltage of the nMIS, and the threshold voltage of the pMIS is controlled by negative fixed charges induced in the BOX layer.

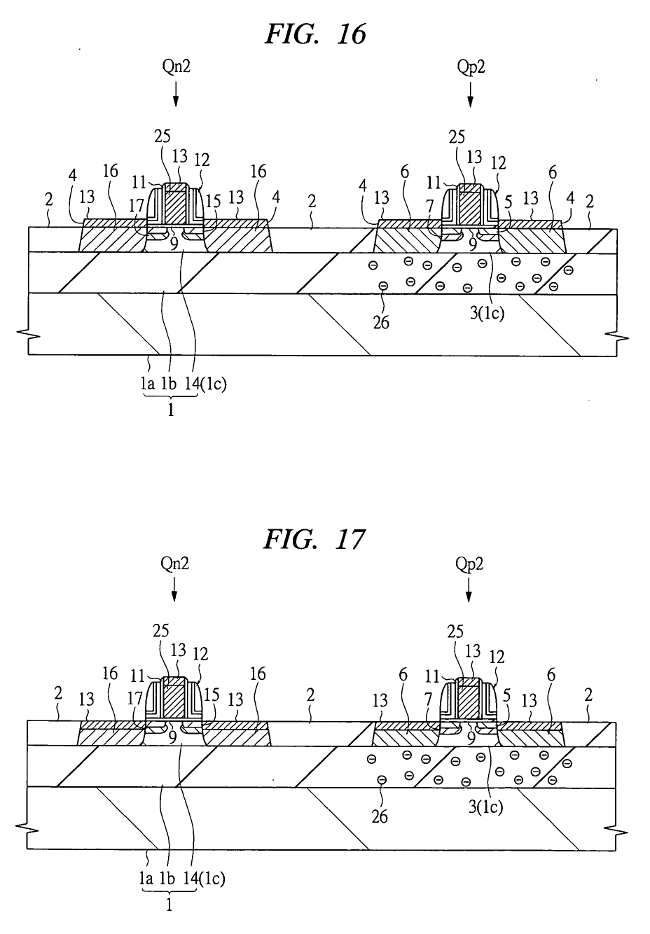

The second embodiment will be described with reference to FIG. 16. FIG. 16 is a sectional view of a principal portion of a SOI substrate showing a full-depletion type SOI device according to the second embodiment. Note that a second embodiment, excluding the constitution of the gate electrode and the fixed charges induced in the BOX layer, is identical to the above first embodiment and therefore the explanation thereof will be omitted.

Gate electrodes 25 made of metal materials are formed on the gate insulators 9 of the pMIS Qp2 and the nMIS Qn2. A material capable of setting the optimum threshold voltage to the nMIS Qn1, such as platinum or palladium, is used as a metal material of the gate electrode 25. Negative fixed charges 26 are induced in the BOX layer 1b under the n-type well 3 in which the pMIS Qp2 is formed. Since the material of the gate electrode 25 of the pMIS Qp2 is the same as that of the gate electrode 25 of the nMIS Qn2, the pMIS Qp2 normally has the threshold voltage on the enhancement side. However, since negative fixed charges 26 are induced in the BOX layer 1b, the pMIS Qp2 becomes in the same state where the substrate bias is applied thereto and thereby the threshold voltage is shifted to the depletion side. The negative fixed charges 26 can be induced by ion-implanting, for example, indium (In). For example, an amount of indium injected is 10¹⁷ cm⁻³ or more. For example, Indium oxide silicon is formed in part of the BOX layer 1b by injecting indium. The above indium is injected with, for example, an injection energy of 140 keV and a dose amount of 3×10¹² cm⁻².

Note that, as shown in FIG. 17, the diffusion layer 6 of the pMIS Qp2 and the diffusion layer 16 of the nMIS Qn2 may be formed only in the SOI layer 1c without forming the silicon layer 4.

### Third Embodiment

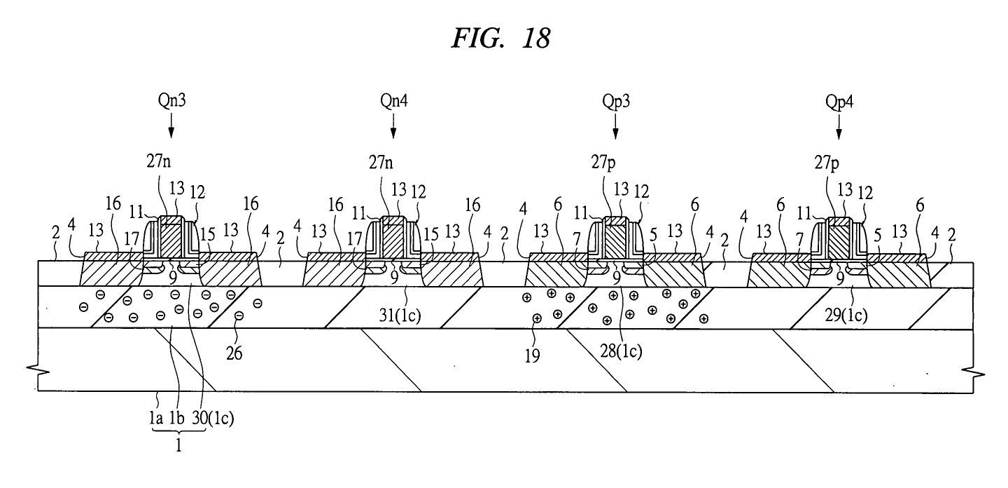

FIG. 18 is a sectional view of a principal portion of a SOI substrate showing a full-depletion type SOI device according to a third embodiment. A CMOS device is illustrated as the full-depletion type SOI device. A pMIS Qp3 and an nMIS Qn3 have relatively high threshold voltages and a pMIS Qp4 and an nMIS Qn4 have relatively low threshold voltages. Note that the third embodiment, excluding the constitution of the gate electrode and the fixed charges induced in the BOX layer, is identical to the first embodiment and therefore the explanation thereof will be omitted.

Two pMISs Qp3 and Qp4 and two nMISs Qn3 and Qn4 are formed on the SOI substrate 1. Materials having work functions approximate to those of channel regions of the pMISs Qp3 and Qp4, such as molybdenum or ruthenium, are used as gate materials of gate electrodes 27p of the pMISs Qp3 and Qp4. Since positive fixed charges are induced in the BOX layer 1b under an n-type well 28 in which the pMIS Qp3 is formed, the pMIS Qp3 with a relatively high threshold voltage is formed. Since fixed charges are not induced in the BOX layer 1b under an n-type well 29 in which the PMIS Qp4 is formed, the pMIS Qp4 having a relatively low threshold voltage is formed.

In the same way, materials having work functions approximate to those of channel regions of the nMISs Qn3 and Qn4, such as platinum or lead, are used as gate materials of gate electrodes 27n of the nMISs Qn3 and Qn4. Since negative fixed charges are induced in the BOX layer 1b under a p-type well 30 in which the nMIS Qn3 is formed, the nMIS Qn3 having a relatively high threshold voltage is formed. Since fixed charges are not induced in the BOX layer 1b under a p-type well 31 in which the nMIS Qn4 is formed, the nMIS Qn4 having a relatively low threshold voltage is formed.

Thus, the two pMISs Qp3 and Qp4 are formed by using the same gate materials as those of the gate electrodes 27p and the threshold voltage of the pMIS Qp3 is controlled by the fixed charges induced in the BOX layer 1b, so that the pMISs Qp3 and Qp4 having two different kinds of threshold voltages can be formed. In the same way, the two nMISs Qn3 and Qn4 are formed by using the same gate materials as those of the gate electrodes 27n and the threshold voltage of the nMIS Qn3 is controlled by the fixed charges induced in the BOX layer 1b, so that the nMISs Qn3 and Qn4 having two different kinds of threshold voltages can be formed. Therefore, four kinds of MISs can be formed on the SOI substrate 1 by using the two kinds of materials. If the threshold voltage is controlled only by selecting the gate material, four kinds of gate materials are required and the manufacturing process becomes complicated. However, such complicated manufacturing process can be avoided in this third embodiment.

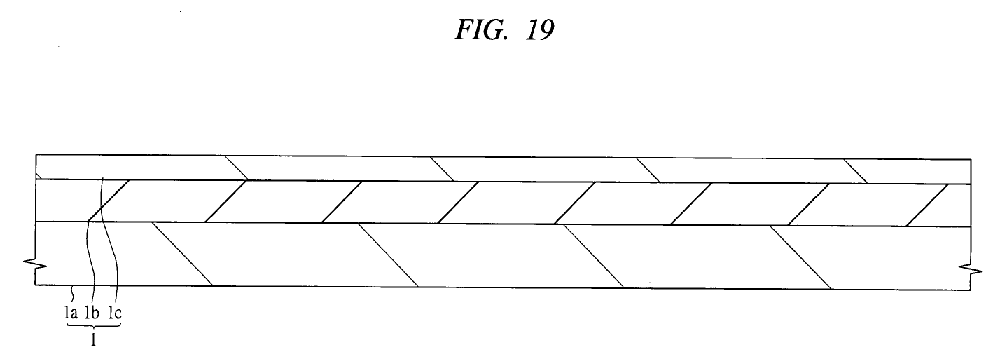

Next, a manufacturing method for the CMOS device according to the third embodiment as shown in FIG. 18 will be described in order of process with reference to FIGS. 19 to 32.

Firstly, as shown in FIG. 19, the SOI substrate 1 manufactured by, for example, the SIMOX method is prepared. The SOI substrate 1 comprises: the supporting substrate la made of p-type single crystal silicon having a specific resistance of, for example, approximately 1 to 10 Ωcm; the SOI layer 1c made of single crystal silicon; and the BOX layer 1b provided between the supporting substrate 1a and the SOI layer 1c. The thickness of the SOI layer 1c is, for example, 50 nm or less and the thickness of the BOX layer 1b is, for example, approximately 100 nm.

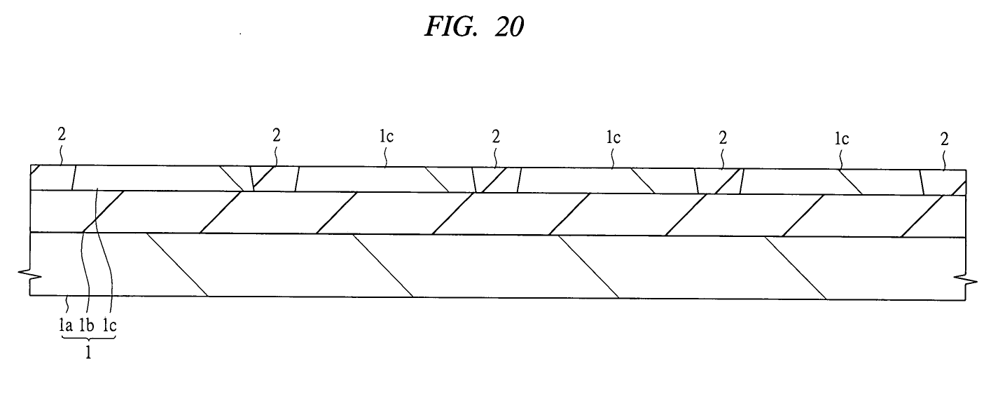

Next, as shown in FIG. 20, the device isolation 2 is formed in the SOI substrate 1. The device isolation 2 is formed as follows. That is, a photoresist film is used as a mask to etch the SOI layer 1c and the device isolation trench extending to the BOX layer 1b is formed. Thereafter, by thermal-oxidizing the SOI substrate 1 at approximately 1000° C., a thin oxide silicon film with a thickness of approximately 10 nm is formed on an inner wall of the trench. This oxide silicon film is formed in order to recover the damages occurring in the inner wall of the trench due to the dry etching and to reduce the stress occurring on the interface between an insulating film embedded into the trench in the next step and the supporting substrate 1a.

Next, an insulating film with a thickness of approximately 0.45 to 0.5 μm is deposited on the SOI layer 1c including the interior of the trench by the CVD (Chemical Vapor Deposition) method, and the insulating film on the top of the trench is polished by the CMP (Chemical Mechanical Polishing) method to planarize the surface thereof.

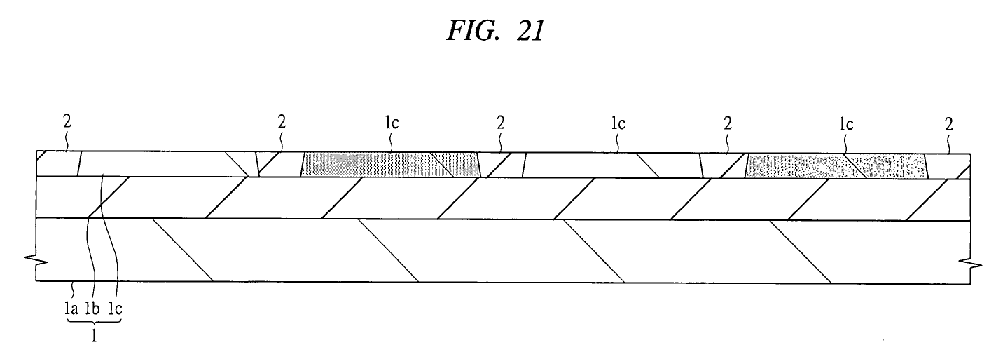

Next, as shown in FIG. 21, an n-type impurity (e.g., boron) is ion-implanted into the SOI layer 1c of a forming region for PMIS Qp4. Further, a p-type impurity is ion-implanted into a channel region of the pMIS Qp4. In the same way, a p-type impurity (e.g., boron) is ion-implanted into the SOI layer 1c of a forming region for nMIS Qn4. Further, an n-type impurity is ion-implanted into a channel region of the nMIS Qn4.

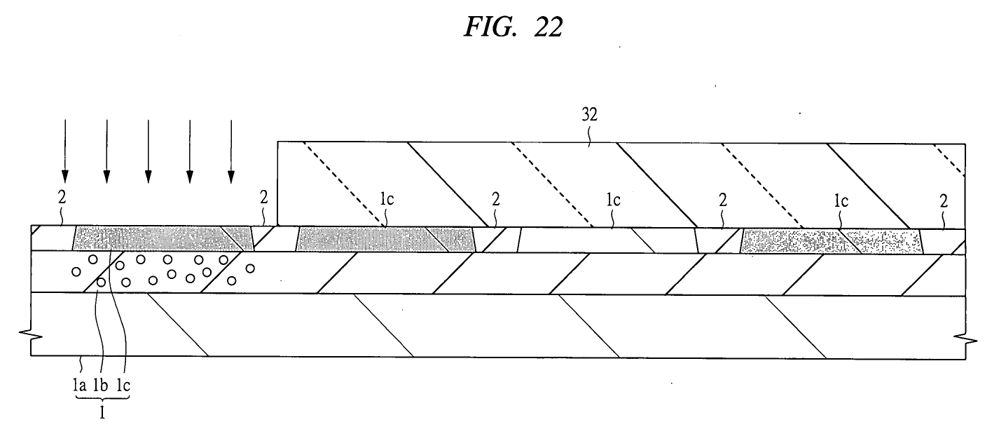

Next, as shown in FIG. 22, the respective forming regions for pMISs Qp3 and Qp4 and the nMIS Qn4 are covered with a photoresist film 32. The p-type impurity (e.g., boron) is ion-implanted into the SOI layer 1c of the forming region for nMIS Qn3. Further, the p-type impurity is ion-implanted into the channel region of the nMIS Qn3. Subsequently, indium is ion-implanted into the BOX layer 1b.

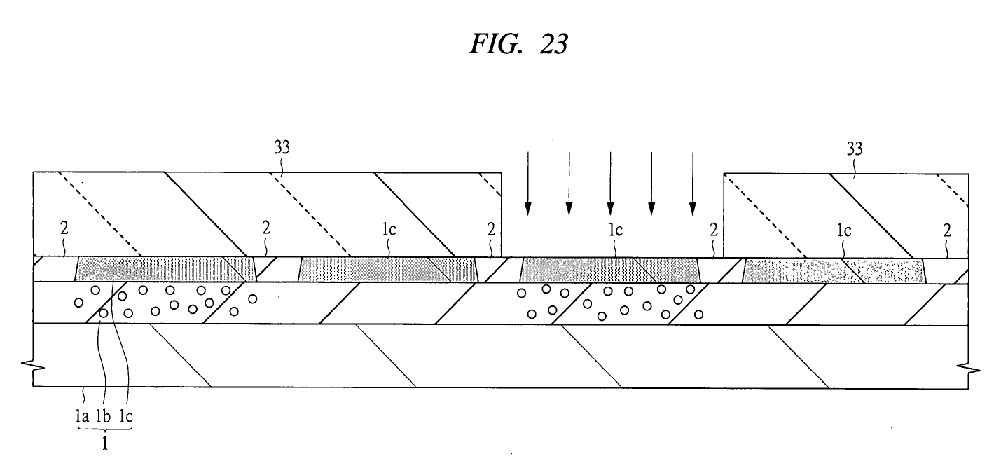

Next, as shown in FIG. 23, after the photoresist film 32 is removed, the respective forming regions for pMIS Qp4 and nMISs Qn3 and Qn4 are covered with a photoresist film 33. The n-type impurity (e.g., phosphorus) is ion-implanted into the SOI layer 1c of the forming region for pMIS Qp3. Further, the n-type impurity is ion-implanted into the channel region of the pMIS Qp3. Subsequently, nitrogen is ion-implanted into the BOX layer 1b.

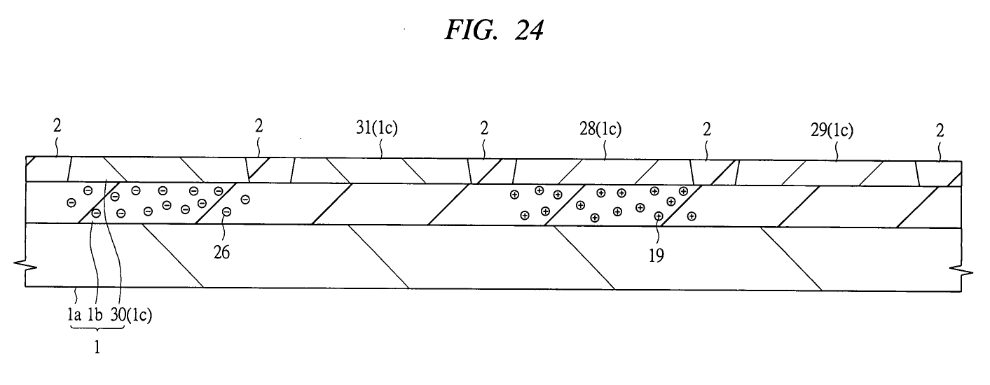

Next, as shown in FIG. 24, after the photoresist film 33 is removed, the impurities are diffused by performing the heat treatment at approximately 1000° C. Thereby, n-type wells 28 and 29, p-type wells 30 and 31, and the threshold voltage control layer are formed in the SOI layer 1c. Further, negative fixed charges 26 are induced in the BOX layer 1b of the forming region for nMIS Qn3, and positive fixed charges 19 are induced in the BOX layer 1b of the forming region for pMIS Qp3.

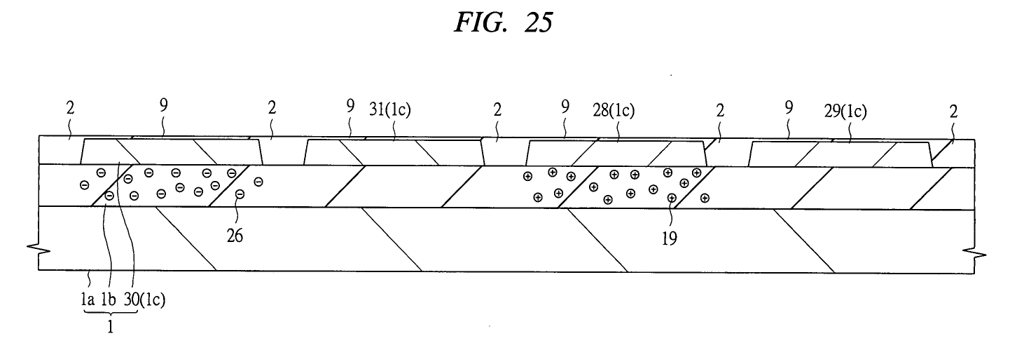

Next, as shown in FIG. 25, after the surface of the SOI layer 1c (n-type wells 28 and 29 and p-type wells 30 and 31) is wet-cleaned by using a fluorinated acid base liquid, the gate insulator 9 is formed on each surface of the n-type wells 28 and 29 and the p-type wells 30 and 31. A silicon oxide film, an oxynitride film, or a high dielectric constant film is used as the gate insulator 9.

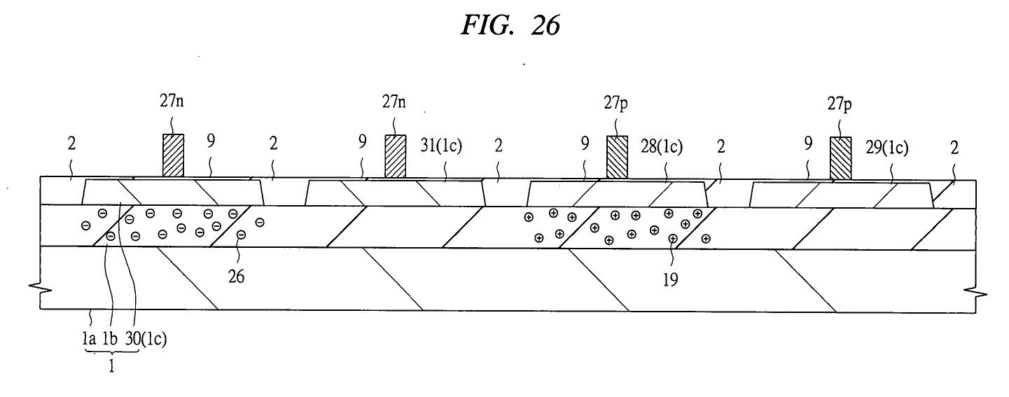

Next, as shown in FIG. 26, a metal film with a thickness of approximately 200 nm is deposited on the gate insulator 9 by the sputtering method. A material having a work function approximate to those of the channel regions of the pMISs Qp3 and Qp4, such as molybdenum or ruthenium, is used for the metal film. Subsequently, the metal film is dry-etched by using the photoresist film as a mask and gate electrodes 27p each made of the metal film are formed. In the same way, a metal film with a thickness of approximately 200 nm is deposited on each gate insulator 9 by the sputtering method. A material having a work function approximate to those of the channel regions of the nMISs Qn3 and Qn4, such as platinum or lead, is used for the metal film. Subsequently, the metal film is dry-etched by using the photoresist film as a mask and gate electrodes 27n each made of the metal film are formed.

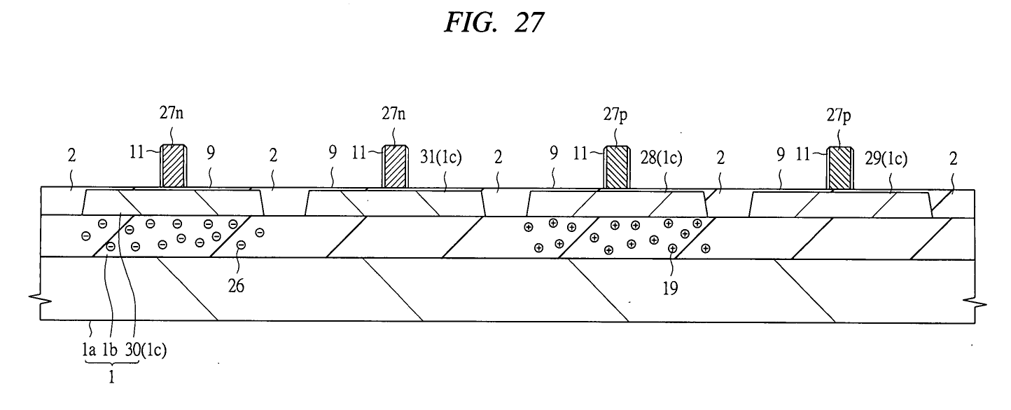

Next, as shown in FIG. 27, after an insulating film with a thickness of, for example, approximately 10 nm is deposited on the gate electrode 10 by the CVD method, the insulating film is anisotropic-etched to form offset spacers 11 on the side walls of the gate electrodes 27n and 27p.

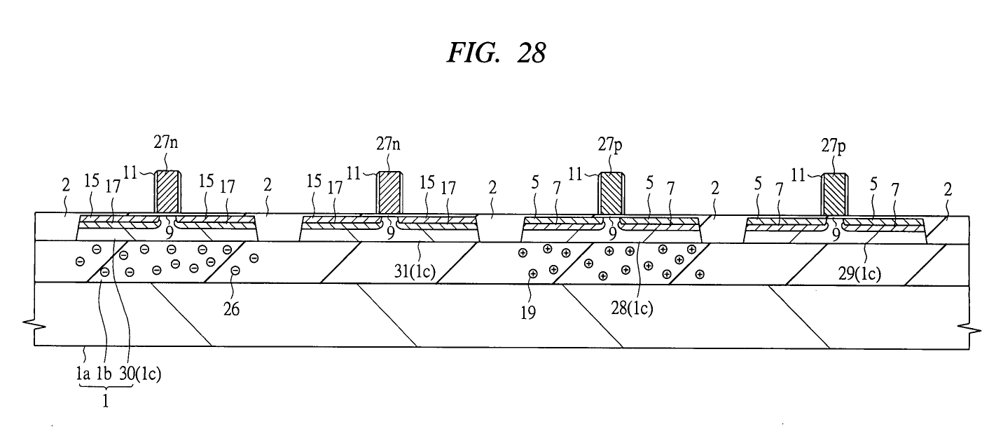

Next, as shown in FIG. 28, the forming regions for nMISs Qn3 and Qn4 are covered with a photoresist film. The p-type impurities (e.g., boron) are ion-implanted into the n-type wells 28 and 29 on both sides of each gate electrode 27p, and the n-type impurity (e.g., arsenic) is ion-implanted into a region deeper than the regions into which the p-type impurities are ion-implanted. In the same way, the forming regions for pMISs Qp3 and Qp4 are covered with a photoresist film. The n-type impurities (e.g., arsenic) are ion-implanted into the P-type wells 30 and 31 on both sides of each gate electrode 27n. The p-type impurity (e.g., boron) is ion-implanted into a region deeper than the regions into which the n-type impurities are ion-implanted. Thereafter, the impurities are diffused by performing the heat treatment to form the extension layers 5 and the halo layers 7 in the n-type wells 28 and 29 and to form the extension layers 15 and the halo layers 17 in the p-type wells 30 and 31, respectively.

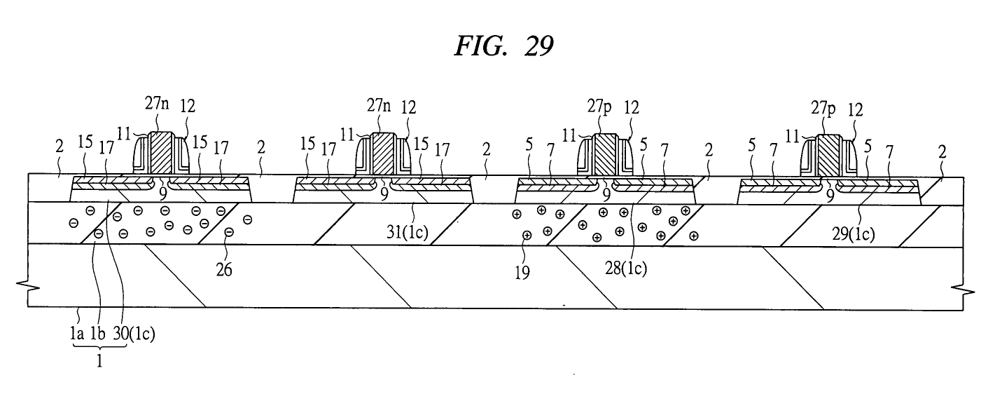

Next, as shown in FIG. 29, an insulating film having a three-layer structure, in which an oxide silicon film, a nitride silicon film, and an oxide silicon film are sequentially deposited on each of the gate electrodes 27n and 27p, is formed. Thereafter, the insulating film is anisotropic-etched to form sidewall spacers 12 on the side walls of the gate electrodes 27n and 27p.

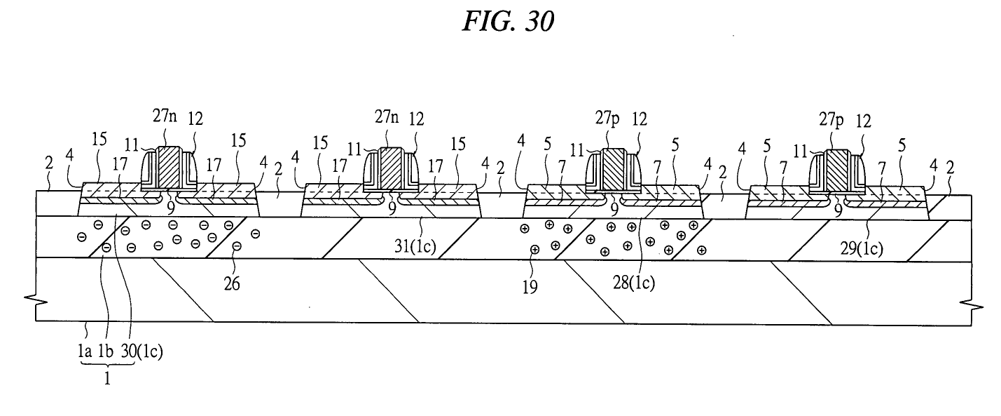

Next, as shown in FIG. 30, after the surface of the SOI layer 1c is wet-cleaned by using the fluorinated acid base liquid, a silicon film 4 is formed on each exposed surface of the SOI layer 1c by the selective epitaxial growth method. The thickness of the silicon film 4 is, for example, approximately 30 nm.

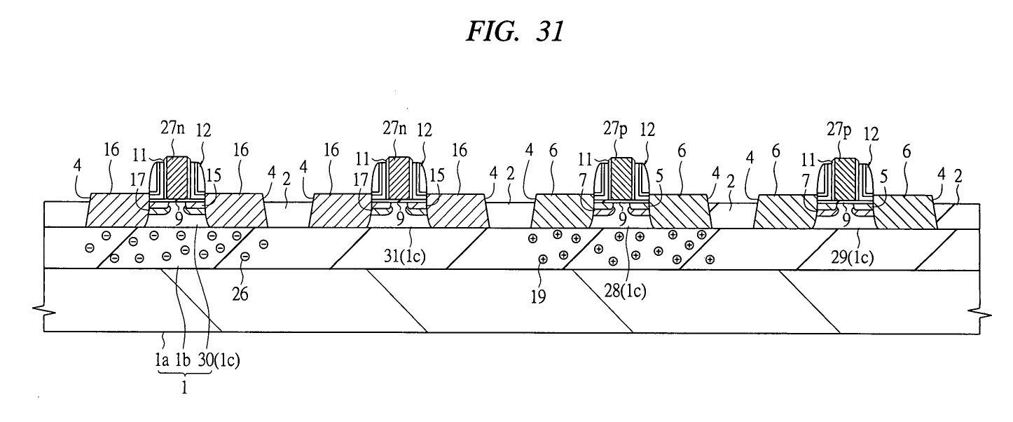

Next, as shown in FIG. 31, the forming regions for nMISs Qn3 and Qn4 are covered with a photoresist film. The p-type impurities (e.g., boron) are ion-implanted into the n-type wells 28 and 29 on both sides of each sidewall spacer 12. In the same way, the forming regions for pMISs Qp3 and Qp4 are covered with a photoresist film. The n-type impurities (e.g., arsenic) are ion-implanted into the p-type wells 30 and 31 on both sides of each sidewall spacer 12. Thereafter, the impurities are diffused by performing the heat treatment to form the diffusion layers 6 in the n-type wells 28 and 29 and the silicon layers 4 and to form the diffusion layers 16 in the p-type wells 30 and 31 and the silicon layer 4. The extension layers 5 formed in the n-type wells 28 and 29 and the diffusion layers 6 formed in the n-type wells 28 and 29 and the silicon layer 4 serve as sources and drains for the pMISs Qp3 and Qp4. The extension layers 15 formed in the p-type wells 30 and 31 and the diffusion layers 16 formed in the p-type wells 30 and 31 and the silicon layer 4 serve as sources and drains for the nMISs Qn3 and Qn4.

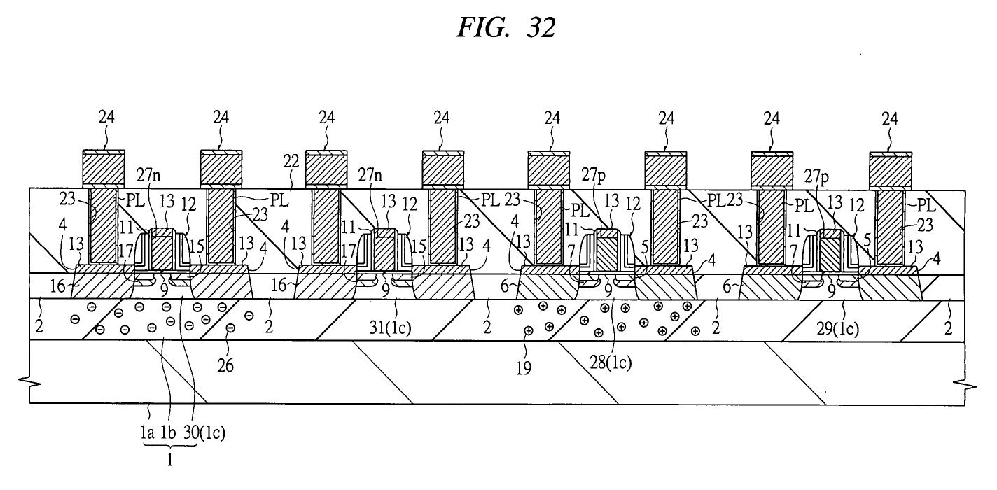

Next, as shown in FIG. 32, after each surface of the silicon layer 4 and the gate electrodes 27n and 27p is cleaned, a cobalt or nickel film is deposited on each of the silicon layer 4 and the gate electrodes 27n and 27p by the sputtering method. Subsequently, by performing the heat treatment at approximately 600° C. for approximately one minute, a silicide film 13 is formed on the exposed portion (diffusion layers 6 and 16) of the silicon layers 4 and the gate electrodes 27n and 27p. Additionally, after the unreacted cobalt or nickel film is removed by the etching, the resistance of the silicide film 13 is made lower, for example, by performing the heat treatment at 700 to 800° C. for approximately one minute.

Next, after an interlayer insulating film 22 is deposited on the silicide film 13, the insulating film 22 is etched by using a photoresist film as a mask to form connection holes 23. Then, after a plug PL is formed into each connection hole 23, a metal film is deposited on the interlayer insulating film 22. The metal film is etched by using a photoresist film as a mask to form wirings 24. Thereby, the CMOS device according to the third embodiment is almost completed.

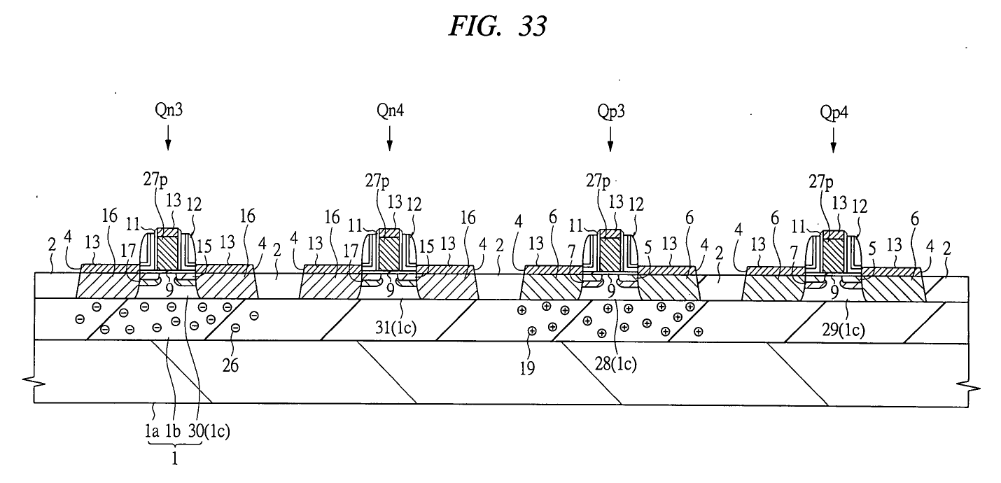

Note that although the gate electrodes 27p of the pMISs Qp3 and Qp4 and the gate electrodes 27n of the nMISs Qn3 and Qn4 are formed by using the different gate materials in the third embodiment, they may be formed by using the same gate material. FIG. 33 is a sectional view of a principal portion of a SOI substrate showing a CMOS device in which a material having a work function approximate to that of the channel region of the PMIS is used as each gate material of the pMIS and nMIS. One kind of metal material, such as molybdenum or ruthenium, is used as each gate material of the pMISs Qp3 and Qp4 and the nMISs Qn3 and Qn4. Thereby, the threshold voltages of the nMISs Qn3 and Qn4 are shifted to the depletion side. However, the threshold voltage of the nMIS Qn3 rises by the negative fixed charges induced in the BOX layer 1b.

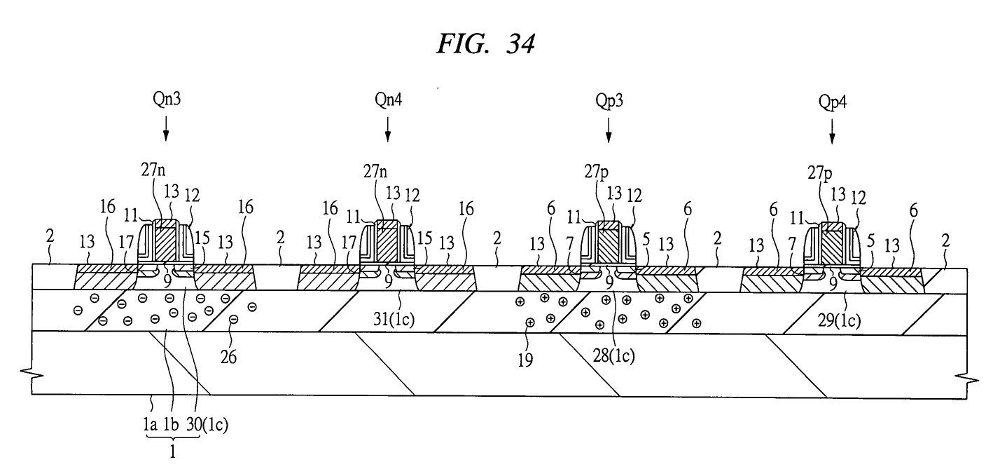

Further, as shown in FIG. 34, the diffusion layers 6 of the pMISs Qp3 and Qp4 and the diffusion layers 16 of the nMISs Qn3 and Qn4 may be formed only in the SOI layer 1c without forming the silicon layer 4.

Additionally, the pMISs Qp3 and Qp4 with two different kinds of threshold voltages and the nMISs Qn3 and Qn4 with two different kinds of threshold voltages are formed in the SOI substrate 1 in the third embodiment. However, the present invention is not limited to the third embodiment, and the pMISs or nMISs with three or more different kinds of threshold voltages may be formed. For example, if three kinds of regions, in which the amounts of the fixed charges induced in the BOX layer 1c are different from one another, are formed by ion implantation, the pMISs with the three different kinds of threshold voltages can be formed in the SOI substrate.

Thus, according to the third embodiment, since the fixed charges are induced in the BOX layer 1b of the SOI substrate 1 and each threshold voltage of the PMIS or nMIS is controlled, the pMISs or nMISs having two or more kinds of threshold voltages can be formed in the full-depletion type SOI device on the same SOI substrate 1.

### Fourth Embodiment

The metal materials are used as the gate materials of the pMIS Qp1 and the nMIS Qn1 in the above-described first embodiment. However, a polycrystalline silicon film, in which a p-type impurity is introduced, is used in a fourth embodiment.

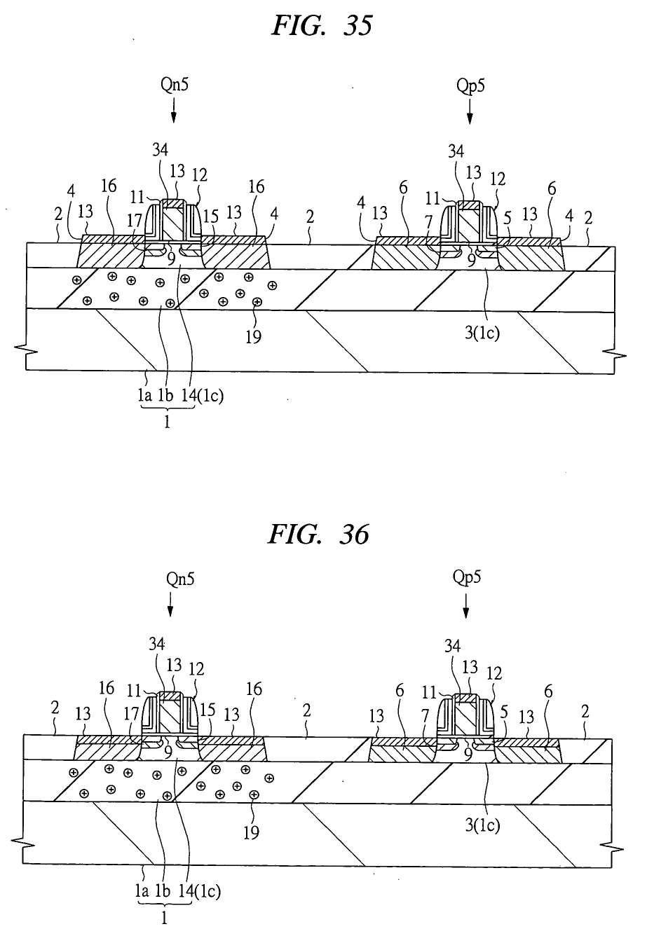

Hereinafter, the fourth embodiment will be described with reference to FIGS. 35. FIG. 35 is a sectional view of a principal portion of a SOI substrate showing a full-depletion type SOI device according to the fourth embodiment. Note that the fourth embodiment is identical to the above-described first embodiment except for the constitution of the gate electrode and the fixed charges induced in the BOX layer and therefore the description thereof will be omitted.

Gate electrodes 34 made of polycrystalline silicon films are formed on the gate insulators 9 of pMIS Qp5 and nMIS Qn5. The p-type impurity (e.g., boron) having a concentration capable of setting the optimum threshold voltage to the PMIS Qp5 is introduced into the polycrystalline silicon film. Additionally, positive fixed charges 19 are induced in the BOX layer 1b under the p-type well 14 in which the nMIS Qn5 is formed. Since a material of a gate electrode 34 of the nMIS Qn5 is identical to that of the gate electrode 34 of the pMIS Qp5, the nMIS Qn5 normally has the threshold voltage on the enhancement side. However, since the positive fixed charges 19 are induced in the BOX layer 1b, the nMIS Qn5 becomes in the same state as a state where the substrate bias is applied and the threshold voltage is shifted to the depletion side. The positive fixed charges 19 can be induced by, for example, ion-implanting nitrogen.

Note that, as shown in FIG. 36, the diffusion layer 6 of the pMIS Qp5 and the diffusion layer 16 of the nMIS Qn5 may be formed only in the SOI layer 1c without forming the silicon layer 4.

### Fifth Embodiment

In a fifth embodiment, a polycrystalline silicon film, in which an n-type impurity is introduced, is used as a gate material.

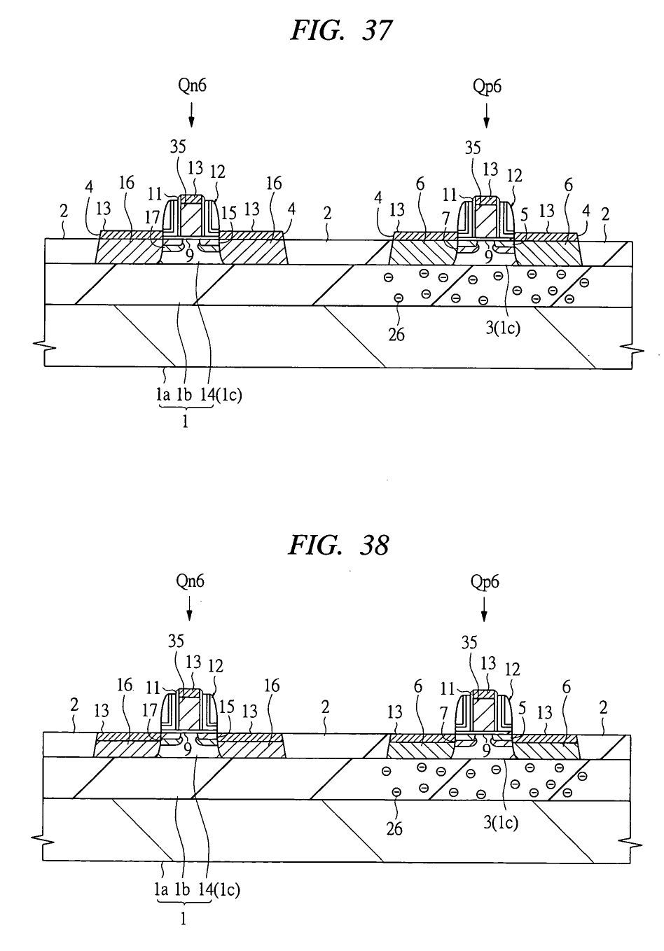

The fifth embodiment will be described with reference to FIG. 37. FIG. 37 is a sectional view of a principal portion of a SOI substrate showing a full-depletion type SOI device according to the fifth embodiment. Note that the fifth embodiment is identical to the above-described second embodiment except for the configuration of the gate electrode and the fixed charges induced in the BOX layer and therefore the description thereof will be omitted.

Gate electrodes 35 made of polycrystalline silicon films are formed on the gate insulators 9 of pMIS Qp6 and nMIS Qn6. The n-type impurity (e.g., phosphorus) having a concentration capable of setting the optimum threshold voltage to the nMIS Qn6 is introduced into the polycrystalline silicon film. Additionally, the negative fixed charges 26 are induced in the BOX layer 1b under the n-type well 3 in which the pMIS Qp6 is formed. Since a material of the gate electrode 35 of the PMIS Qp6 is the same as that of the gate electrode 35 of the nMIS Qn6, the pMIS Qp6 normally has the threshold voltage on the enhancement side. However, since the negative fixed charges 26 are induced in the BOX layer 1b, the pMIS Qp6 becomes in the same state as a state where the substrate bias is applied and thereby the threshold voltage is shifted to the depletion side. The negative fixed charges 26 can be induced, for example, by ion-implanting indium.

Note that, as shown in FIG. 38, the diffusion layer 6 of the pMIS Qp6 and the diffusion layer 16 of the nMIS Qn6 may be formed only in the SOI layer 1c without forming the silicon layer 4.

### Sixth Embodiment

In a sixth embodiment, a polycrystalline silicon film in which a p-type impurity is introduced is used as a gate material of the pMIS, and a polycrystalline silicon film in which an n-type impurity is introduced is used as a gate material of the nMIS.

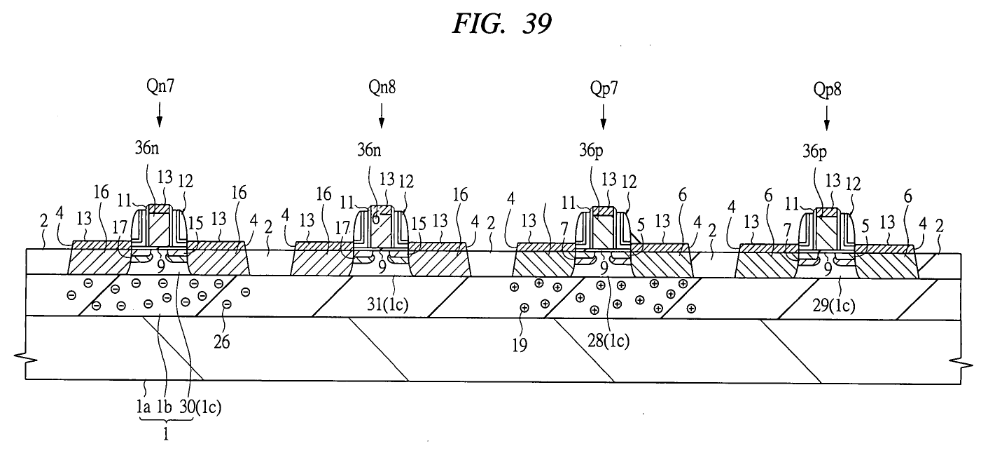

The sixth embodiment will be described below with reference to FIG. 39. FIG. 39 is a sectional view of a principal portion of a SOI substrate showing a full-depletion type SOI device according to a sixth embodiment. A CMOS device is illustrated as the full-depletion type SOI device. A pMIS Qp7 and nMIS Qn7 have relatively high threshold voltages. A PMIS Qp8 and nMIS Qn8 have relatively low threshold voltages. Note that the sixth embodiment is identical to the above-described third embodiment except for the configuration of the gate electrode and the fixed charges induced in the BOX layer and therefore the description thereof will be omitted.

Two pMISs Qp7 and Qp8 and two nMISs Qn7 and Qn8 are formed on the SOI substrate 1. A polycrystalline silicon film in which the p-type impurity (e.g., boron) is introduced is used as each gate material of gate electrodes 36p of the pMISs Qp7 and Qp8. Further, since positive fixed charges 19 are induced in the BOX layer 1b under the n-type well 3 in which the pMIS Qp7 is formed, the pMIS Qp7 with a relatively high threshold voltage is formed. Since the fixed charges is not induced in the BOX layer 1b under the n-type well 3 in which the pMIS Qp8 is formed, the pMIS Qp8 with a relatively low threshold voltage is formed.

In the same way, a polycrystalline silicon film in which the n-type impurity (e.g., phosphorus) is introduced is used as each gate material of gate electrodes 36n of the nMISs Qn7 and Qn8. Since the negative fixed charges 26 are induced in the BOX layer 1b under the p-type well 14 in which the nMIS Qn7 is formed, the nMIS Qn7 with a relatively high threshold voltage is formed. Further, since the fixed charges are not induced in the BOX layer 1b under the p-type well 14 in which the nMIS Qn8 is formed, the nMIS Qn8 having a relatively low threshold voltage is formed.

Thus, if the polycrystalline silicon film is used as the gate material, four kinds of MISs can be formed in the SOI substrate 1 by using two kinds of gate materials. Therefore, this embodiment can also obtain the same effect as that of the above-mentioned third embodiment, that is, the effect capable of avoiding complications in the manufacturing process.

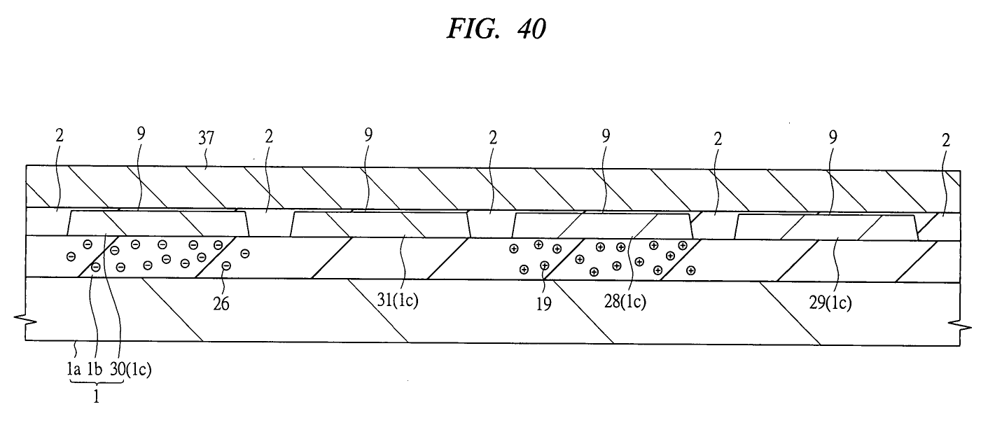

Next, a manufacturing method for the CMOS device that is the sixth embodiment as shown in FIG. 39 will be described in order of process with reference to FIGS. 40 to 42. Note that the sixth embodiment is identical to the above-described third embodiment, except for the configuration of the gate electrode and the process of forming the same, and therefore the description thereof will be omitted and a process of forming the gate electrode will be described.

After the gate insulators 9 are formed on the surface of the SOI layer 1c as described in the third embodiment with reference to FIG. 25, an amorphous silicon film 37 with a thickness of, for example, approximately 200 nm is deposited on the gate insulators 9 by the CVD method.

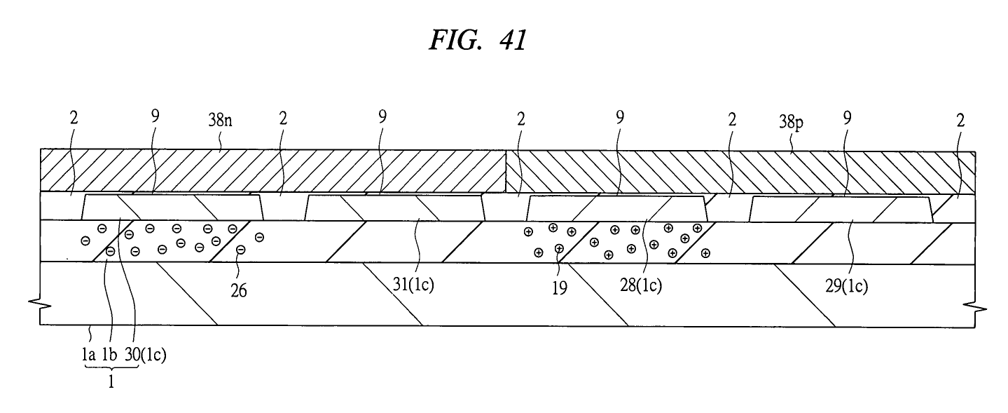

Next, as shown in FIG. 41, forming regions for nMISs Qn7 and Qn8 are covered with the photoresist film. P-type impurities (e.g., boron) are ion-implanted into the amorphous silicon film 37 of the forming regions for pMISs Qp7 and Qp8. Subsequently, the forming regions for pMISs Qp7 and Qp8 are covered with a photoresist film. N-type impurities (e.g., phosphorus) are ion-implanted into the amorphous silicon film 37 of the forming regions for nMISs Qn7 and Qn8. Then, the above impurities are diffused by performing the heat treatment and thereby an polycrystalline silicon layer 38p whose conductivity type is “p” is formed in the forming regions for pMISs Qp7 and Qp8 and a polycrystalline silicon layer 38n whose conductivity type is “n” is formed in the forming region for nMISs Qn7 and Qn8.

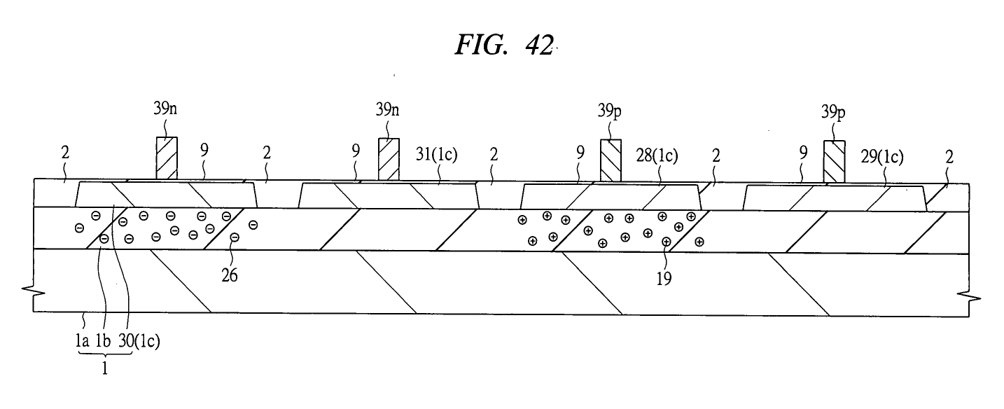

Next, as shown in FIG. 42, the polycrystalline silicon layers 38p and 38n are dry-etched by using a photoresist film as a mask, gate electrodes 39p are formed in the forming regions for pMISs Qp7 and Qp8, and gate electrodes 39n are formed in the forming regions for nMISs Qn7 and Qn8. Thereafter, the same process as that of the third embodiment is performed.

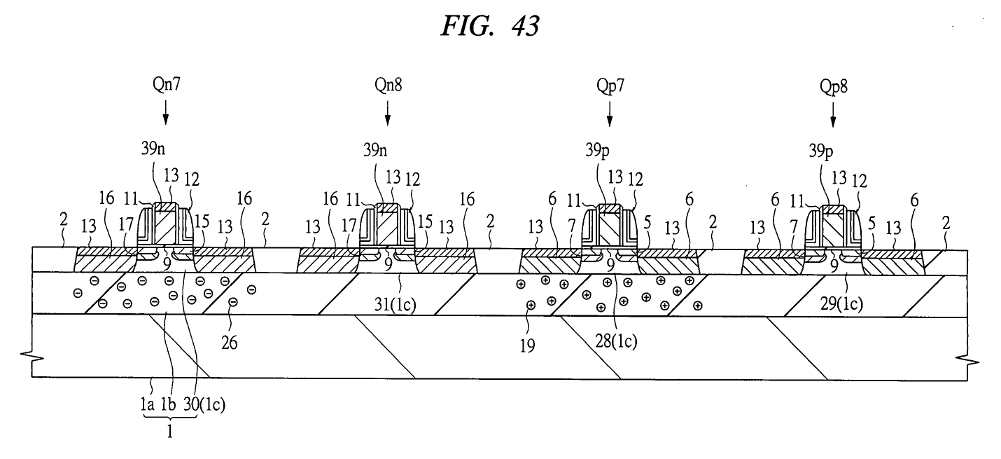

Note that, as shown in FIG. 43, the diffusion layers 6 of the pMISs Qp7 and Qp8 and the diffusion layers 16 of the nMISs Qn7 and Qn8 may be formed only in the SOI layer 1c without forming the silicon layer 4.

Thus, according to the sixth embodiment, even if the polycrystalline silicon film is used as a gate material, the fixed charges 19 and 26 are induced in the BOX layer 1b of the SOI substrate 1 and each threshold voltage of the pMISs Qp7 and Qp8 or nMIS Qn7 and Qn8 is controlled, respectively, so that the pMISs or nMISs with two or more kinds of threshold voltages can be formed in the full-depletion. type SOI device on the same SOI substrate 1.

As described above, the embodiments of the invention made by the present inventors have been specifically described. However, needless to say, the present invention is not limited to the above embodiments and may be variously altered and modified without departing from the gist thereof.

For example, in the above embodiments, the threshold voltage of the MISFET has been controlled by dividing the material for inducing the fixed charges into a region for ion-implantation and a region for no ion-implantation. However, the threshold voltage of MISFET may be controlled by changing an amount ion-implanted into the BOX layer.

Additionally, for example, in the above embodiments, the case of applying the present invention to the full-depletion type SOI device has been described. However, the present invention is not limited to this case and may be applied to, for example, a partial-depletion type SOI device.

The present invention can be applied to a semiconductor device including a plurality of MISFETs formed on the SOI substrate and having the different threshold voltages and o a manufacturing method for the same.

1. A semiconductor device comprising:
(a) an SOI substrate having a SOI layer formed on a supporting substrate through a BOX layer;
(b) a first region formed in said SOI layer and having a first conductivity type;
(c) a second region formed in said SOI layer and having a second conductivity type;
(d) a first MISFET formed in said first region of said SOI layer and having a channel with said second conductivity type; and
(e) a second MISFET formed in said second region of said SOI layer and having a channel with said first conductivity type,
wherein said BOX layer in said first region has a fixed charge.

2. The semiconductor device according to claim 1,
wherein the fixed charge is nitrogen.

3. The semiconductor device according to claim 2,
wherein said BOX layer in said first region contains oxynitride silicon.

4. The semiconductor device according to claim 1,
wherein said fixed charge is indium.

5. The semiconductor device according to claim 4,
wherein said BOX layer in said first region contains indium oxide silicon.

6. A semiconductor device comprising:
(a) a SOI substrate having a SOI layer formed on a supporting substrate through a BOX layer;
(b) a first region formed in said SOI layer and having a first conductivity type;
(c) a second region formed in said SOI layer and having a second conductivity type;
(d) a first MISFET formed in said first region of said SOI layer and having a channel with said second conductivity type;
(e) a second MISFET formed in said second region of said SOI layer and having a channel with said first conductivity type; and
(f) a fixed charge induced in said BOX layer under said second region,
wherein each gate electrode of said first and second MISFETs is made of such a gate material that a predetermined threshold voltage can be obtained in said first MISFET.

7. The semiconductor device according to claim 6,
wherein a concentration of said fixed charge is equal to or more than 10¹⁷ cm⁻³.

8. The semiconductor device according to claim 6,
wherein if a channel of the first MISFET is a p type, said gate material is molybdenum or ruthenium.

9. The semiconductor device according to claim 8,
wherein said fixed charge induced in said BOX layer under said second region is a positive charge.

10. The semiconductor device according to claim 9,
wherein said positive charge is nitrogen.

11. The semiconductor device according to claim 6,
wherein if a channel of said first MISFET is an n type, said gate material is platinum or lead.

12. The semiconductor device according to claim 11,
wherein said fixed charge formed in said BOX layer under said second region is a negative charge.

13. The semiconductor device according to claim 12,
wherein said negative charge is indium.

14. The semiconductor device according to claim 6,
wherein said gate material is polycrystalline silicon having said second conductivity type.

15. A semiconductor device comprising:
(a) a SOI substrate having a SOI layer formed on a supporting substrate through a BOX layer;
(b) a first region formed in said SOI layer and having a first conductivity type;
(c) a third region formed in said SOI layer and having said first conductivity type;
(d) a first MISFET formed in said first region of said SOI layer and having a channel with a second conductivity type;
(e) a third MISFET formed in said third region of said SOI layer and having a channel with said second conductivity type; and
(f) a fixed charge induced in said BOX layer under said third region,
wherein each gate electrode of said first and third MISFETs is made of such a gate material that a predetermined threshold voltage can be obtained in said first MISFET.

16. The semiconductor device according to claim 15,
wherein a concentration of said fixed charge is equal to or more than 10¹⁷ cm⁻³.

17. The semiconductor device according to claim 15,
wherein if each channel of said first and third MISFETs is a p type, said fixed charge induced in said BOX layer under said third region is a positive charge.

18. The semiconductor device according to claim 17,
wherein said positive charge is nitrogen.

19. The semiconductor device according to claim 15,
wherein if each channel of said first and third MISFETs are an n type, said fixed charge induced in said BOX layer under said third region is a negative charge.

20. The semiconductor device according to claim 19,
wherein said negative charge is indium.

21-39. (canceled)
